(19) United States
(12) Patent Application Publication
(10) Pub. No.: US 2004/0251817 A1
(43) Pub. Date: Dec. 16, 2004

(54) Electronic device with auxiliary light

(76) Inventor: Ying-Yu Lu, Taichung (TW)

Correspondence Address: BIRCH STEWART KOLASCH & BIRCH, PO BOX 747, FALLS CHURCH, VA, 22040-0747, US

(21) Appl. No.: 10/862,312

(22) Filed: Jun. 8, 2004

(30) Foreign Application Priority Data
Jun. 10, 2003 (TW) 092115769

(51) Int. Cl. H05B 33/14; H05B 33/00

(52) U.S. Cl. 313/504; 313/503; 313/506

(57) ABSTRACT

An electronic device with an auxiliary light includes a display module. The display module comprises a substrate, a display area and a light-emitting area. In this case, the substrate has a first surface and a second surface which is opposite to the first surface. The display area has a first electrode, an organic functional layer and a second electrode. The organic functional layer is sandwiched between the first electrode and the second electrode. The first electrode is disposed on the first surface of the substrate. The light-emitting area has a third electrode, an organic functional layer and a fourth electrode. The organic functional layer is sandwiched between the third electrode and the fourth electrode, the third electrode is disposed on the first surface or the second surface of the substrate.

### BACKGROUND OF THE INVENTION

1. Field of Invention

The invention relates to an electronic device, and more particularly to an electronic device with an auxiliary light.

2. Related Art

As more and more innovative electronic products are developed, we may find that new generation of electronic products are featuring multiple functions. For instance, an image capture system applies to a mobile phone. That is, wireless communication and photograph function are integrated with electronic device. Thus, one can use mobile phone to show any image, and save it in a mobile phone or transmit to another user via wireless communication system. Before taking any image, one can use the picture preview window, which is normally a flat display, for image preview. In addition, auxiliary light, e.g. flash, may be integrated with this device so as to compensate for an insufficient intensity of environmental light.

In terms of known technology, however, the auxiliary light will need to be assembled with mobile phone and separated from other modules, such as the display panel, the image capture system, and the like. That is, not only the overall manufacturing cost but also the number of modules in the electronic device is increased, when the electronic device needs flash light, an auxiliary light module has to be added to the original electronic device. In addition, the overall production lead-time is prolonged because the manufacturing processes become more complicated. Under consideration of the production efficiency, the prior art is not suitable for the industry applications.

### SUMMARY OF THE INVENTION

In view of the above-mentioned problems, an electronic device having a single module of display panels and auxiliary lights is provided.

In a preferred embodiment of this invention, an electronic device with an auxiliary light is provided. The electronic device has a display module, and the display module includes a substrate, a display area and a light-emitting area. The substrate has a first surface and a second surface opposite to the first surface. The display area has a first electrode, an organic functional layer and a second electrode. The organic functional layer is sandwiched between the first electrode and the second electrode, and the first electrode is disposed on the first surface of the substrate. The light-emitting area has a third electrode, an organic functional layer and a fourth electrode. The organic functional layer is sandwiched between the third electrode and the fourth electrode, and the third electrode is disposed on the first surface or second surface of the substrate.

In a preferred embodiment of this invention, an electronic device with an auxiliary light is provided. The electronic device has a display module, and the display module includes a substrate, a first display area, a first light-emitting area, a second display area and a second light-emitting area. The substrate has a first surface and a second surface opposite to the first surface. The first display area has a first electrode, an organic functional layer and a second electrode. The organic functional layer is sandwiched between the first electrode and the second electrode, and the first electrode is disposed on the first surface of the substrate. The first light-emitting area has a third electrode, an organic functional layer and a fourth electrode. The organic functional layer is sandwiched between the third electrode and the fourth electrode, and the third electrode is disposed on the first surface of the substrate. The second display area has a fifth electrode, an organic functional layer and a sixth electrode. The organic functional layer is sandwiched between the fifth electrode and the sixth electrode, and the fifth electrode is disposed on second surface of the substrate. The second light-emitting area has a seventh electrode, an organic functional layer and an eighth electrode. The organic functional layer is disposed between the seventh electrode and the eighth electrode, and the seventh electrode is disposed on second surface of the substrate.

In a preferred embodiment of this invention, an electronic device with an auxiliary light is provided. The electronic device has a display module, and the display module includes a first substrate, a display area, a light-emitting area, a second substrate and another display area. The first substrate has a first surface and a second surface opposite to the first surface. The display area has a first electrode, an organic functional layer and a second electrode. The organic functional layer is sandwiched between the first electrode and the second electrode, and the first electrode is disposed on first surface of the first substrate. The light-emitting area has a third electrode, an organic functional layer and a fourth electrode. The organic functional layer is sandwiched between the third electrode and the fourth electrode, and the third electrode is disposed on first surface of the first substrate. The second substrate has a third surface and a fourth surface. The third surface is opposite to the fourth surface, and the fourth surface of the second substrate is opposite to the second surface of the first substrate. Another display area has a fifth electrode, an organic functional layer and a sixth electrode. The organic functional layer is sandwiched between the fifth electrode and the sixth electrode, and the fifth electrode is disposed on the third surface of the second substrate.

In a preferred embodiment of this invention, an electronic device with an auxiliary light is provided. The electronic device has a display module, and the display module includes a first substrate, a display area, a light-emitting area, a second substrate and another light-emitting area. The first substrate has a first surface and a second surface opposite to the first surface. The display area has a first electrode, an organic functional layer and a second electrode. The organic functional layer is sandwiched between the first electrode and the second electrode, and the first electrode is disposed on first surface of the first substrate. The light-emitting area has a third electrode, an organic functional layer and a fourth electrode. The organic functional layer is sandwiched between the third electrode and the fourth electrode, and the third electrode is disposed on the first surface of the first substrate. The second substrate has a third surface and a fourth surface. The third surface is opposite to the fourth surface, and the fourth surface of the second substrate is opposite to the second surface of the first substrate. Another light-emitting area has a seventh electrode, an organic functional layer and an eighth electrode. The organic functional layer is sandwiched between the seventh electrode and the eighth electrode, and the seventh electrode is disposed on the third surface of the second substrate.

As mentioned above, the electronic device with an auxiliary light according to the invention has an OELD (Organic Electroluminescent Display) panel having the display function and the auxiliary light function. That is, the invention utilizes the self-emissive and high brightness properties of the OELD panel so that the device has the functions of displaying information, images and videos as well as the special functions of serving as the auxiliary light (e.g., flash). Compared to the prior art, the invention has combined the display function and the auxiliary light function into a single module by only utilizing the original OELD panel without adding an extra auxiliary light source module. In this case, the number of applied modules can be reduced, the assembling space of the module can become compact, and the electronic device can meet the requirement of miniaturization. Meanwhile, the manufacturing process is less complicated which results in lower production costs and higher production efficiency. Thus, the invention is very suitable for the practical product application and manufacturing. In addition, light-emitting areas may be respectively formed on two opposite surfaces of the substrate in this invention so that the invention may also have the dual auxiliary light functions, which will increase product value and meet different users' requirements.

### BRIEF DESCRIPTION OF THE DRAWINGS

FIG. 1 is a schematic illustration showing an electronic device with an auxiliary light according to a first embodiment of the invention;

FIG. 2A is a schematic top view showing a display module according to the first embodiment of the invention;

FIG. 2B is a schematically cross-sectional view taken along a dashed line A-A in the display module of FIG. 2A;

FIG. 2C is another schematically cross-sectional view taken along the dashed line A-A in the display module of FIG. 2A;

FIG. 3 is an arrangement of schematic illustrations showing the arrangement positions of the display area and the light-emitting area in the first embodiment of the invention;

FIGS. 4A and 4B are an arrangement of schematic illustrations showing light-emitting directions of the display area and the light-emitting area in the first embodiment of the invention;

FIG. 5 is a schematic illustration showing a display module according to a second embodiment of the invention;

FIG. 6 is a schematic illustration showing a display module according to a third embodiment of the invention;

FIGS. 7A and 7B are a set of schematic illustrations showing a display module according to a fourth embodiment of the invention;

FIGS. 8A and 8B are an arrangement of schematic illustrations showing a display module according to a fifth embodiment of the invention;

FIGS. 9A and 9B are an arrangement of schematic illustrations showing a display module according to a sixth embodiment of the invention;

FIGS. 10A and 10B are an arrangement of schematic illustrations showing a display module according to a seventh embodiment of the invention;

FIGS. 11 is a schematic illustration showing a display module according to an eighth embodiment of the invention;

FIG. 12 is a schematic illustration showing a mobile phone according to an embodied example of the invention; and

FIG. 13 is a schematically cross-sectional view showing the mobile phone according to the embodied example of the invention.

### DETAILED DESCRIPTION OF THE INVENTION

The electronic devices with an auxiliary light according to the preferred embodiments of the invention will be described with reference to the accompanying drawings.

### FIRST EMBODIMENT

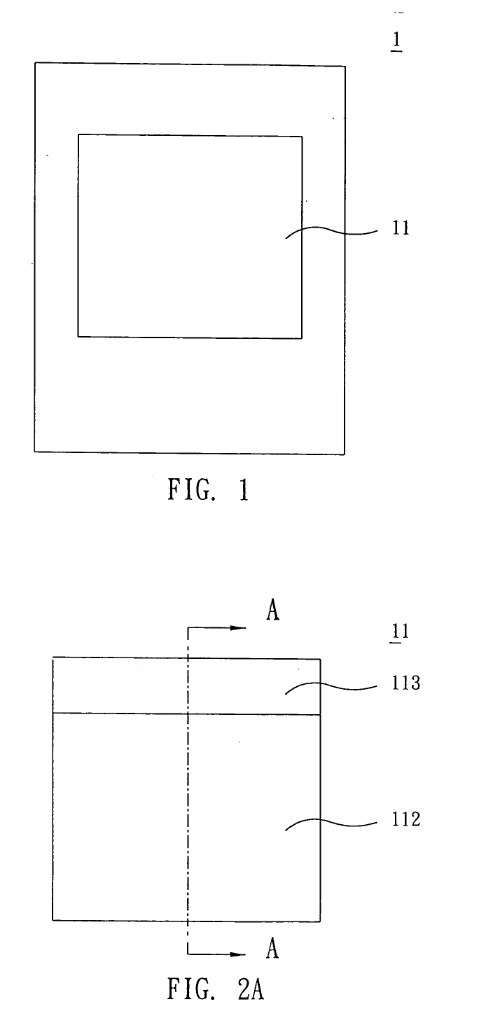

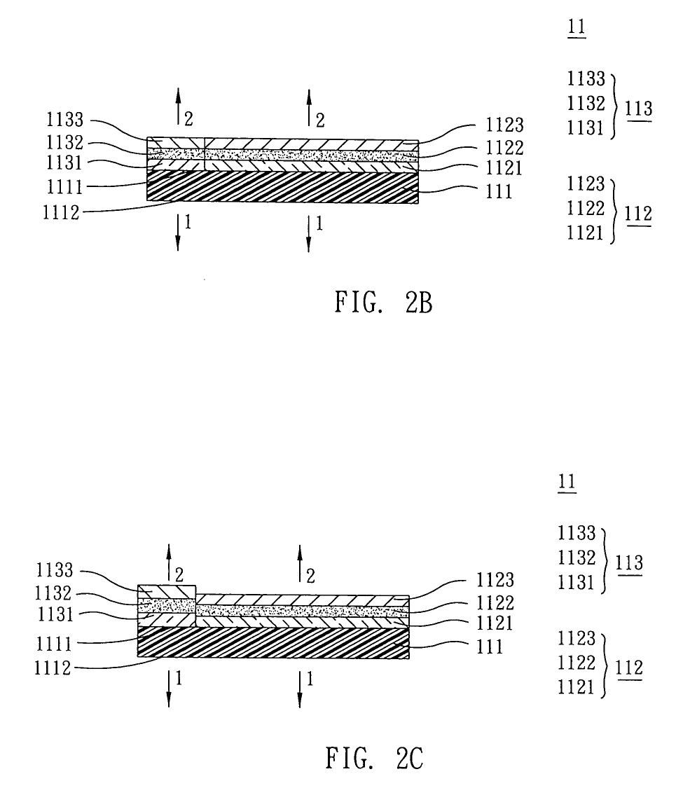

Referring to FIGS. 1, 2A and 2B, the electronic device 1 with an auxiliary light according to first embodiment of the invention includes a display module 11. The display module 11 comprises a substrate 111, a display area 112 and a light-emitting area 113. The substrate 111 has a first surface 1111 and a second surface 1112 opposite to the first surface 1111. The display area 112 has a first electrode 1121, an organic functional layer 1122 and a second electrode 1123. The organic functional layer 1122 is sandwiched between the first electrode 1121 and the second electrode 1123, and the first electrode 1121 is disposed on the first surface 1111 of the substrate 111. The light-emitting area 113 has a third electrode 1131, an organic functional layer 1132 and a fourth electrode 1133. The organic functional layer 1132 is sandwiched between the third electrode 1131 and the fourth electrode 1133, and the third electrode 1131 is disposed on the first surface 1111 of the substrate 111.

In this embodiment, the substrate 111 may be a flexible substrate or a rigid substrate. Meanwhile, the substrate 111 also may be or may not be passed through by light. When the substrate 111 is a transparent substrate, the light from the display area 112 and the light-emitting area 113 are emitted in the directions 1 and 2, as shown in FIG. 2B. When the substrate 111 is an opaque substrate, the light from the display area 112 and the light-emitting area 113 are emitted in the direction 2, as shown in FIG. 2B, wherein the direction 1 is opposite to the direction 2.

In addition, the substrate 111 also may be a plastic substrate or a glass substrate. The flexible substrate and the plastic substrate may be a polycarbonate (PC) substrate, a polyester (PET) substrate, a cyclic olefin copolymer (COC) substrate or a metallocene-based cyclic olefin copolymer (mCOC) substrate.

As shown in FIG. 2B, which is a cross-sectional view taken along the dashed line A-A of the display module 11 of FIG. 2A, the display area 112 has the first electrode 1121, the organic functional layer 1122 and the second electrode 1123. The organic functional layer 1122 is sandwiched between the first electrode 1121 and the second electrode 1123, and the first electrode 1121 is disposed on the first surface 1111 of the substrate 111.

In this embodiment, the first electrode 1121 is formed on the first surface 1111 of the substrate 111 by way of sputtering or ion plating. Herein, the first electrode 1121 usually serves as an anode and the material thereof is usually a transparent conductive metal oxide, such as the indium tin oxide (ITO), the aluminum zinc oxide (AZO), the indium zinc oxide (IZO), or the like.

In addition, the organic functional layer 1122 usually includes a hole-injecting layer, a hole-transporting layer, a light-emitting layer, an electron-transporting layer and an electron-injecting layer (not shown). The organic functional layer 1122 is formed on the first electrode 1121 by way of evaporation, spin coating, ink jet printing, printing, or the like. In addition, the light emitted from the organic functional layer 1122 may be blue, green, red, white or other monochroic light, or the mixed lights.

In addition, the second electrode 1123 is disposed on the organic functional layer 1122. Herein, the second electrode 1123 is formed on the organic functional layer 1122 by way of evaporation or sputtering. In addition, the material of the second electrode 1123 may be one selected from the group of, but not limited to, Aluminum (Al), Calcium (Ca), Magnesium (Mg), Indium (In), Tin (Sn), Manganese (Mn), Silver (Ag), Gold (Au) and Magnesium-containing alloy (e.g., Magnesium-Silver (Mg:Ag) alloy, Magnesium-Indium (Mg:In) alloy, Magnesium-Tin (Mg:Sn) alloy, Magnesium-Antimony (Mg:Sb) alloy, and Magnesium-Tellurium (Mg:Te) alloy), and the like.

Referring again to FIG. 2B, the light-emitting area 113 has the third electrode 1131, the organic functional layer 1132 and the fourth electrode 1133. The organic functional layer 1132 is sandwiched between the third electrode 1131 and the fourth electrode 1133, and the third electrode 1131 is disposed on the first surface 1111 of the substrate 111. Herein, the characteristics and functions of the third electrode 1131 and the fourth electrode 1133 are the same as the first electrode 1121 and the second electrode 1123 of the display area 112, and detailed descriptions thereof will be omitted.

In addition, as shown in FIG. 2C, the thickness of the first electrode 1121, the organic functional layer 1122 and the second electrode 1123 of the display area 112, and the thickness of the third electrode 1131, the organic functional layer 1132 and the fourth electrode 1133 of the light-emitting area 113 may be adjusted according to the actual requirements.

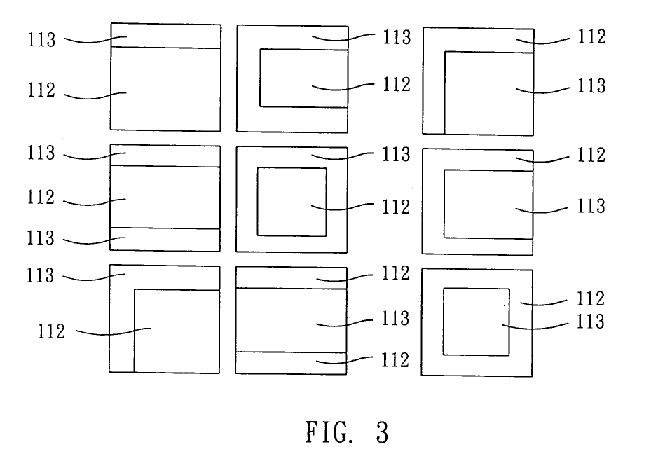

As shown in FIG. 3 again, the light-emitting area 113 is disposed on at least one side of the display area 112. Of course, the display area 112 also may be disposed on at least one side of the light-emitting area 113. Herein, the arrangement and shape relationship between the display area 112 and the light-emitting area 113 and the area sizes thereof may be adjusted according to the actual requirements.

In this embodiment, the display area 112 and the light-emitting area 113 are independently driven. That is, the voltages applied to the display area 112 and the light-emitting area 113 may be different according to the actual requirements. When the light-emitting area 1113 is disabled from providing the auxiliary light, it is also possible to apply a proper voltage to the light-emitting area 113 such that the light-emitting area 113 can present the integral effect (e.g., the light-emitting area 113 also may display texts, images or videos) in conjunction with the display area 112 in order to enhance the overall appearance of the electronic device 1.

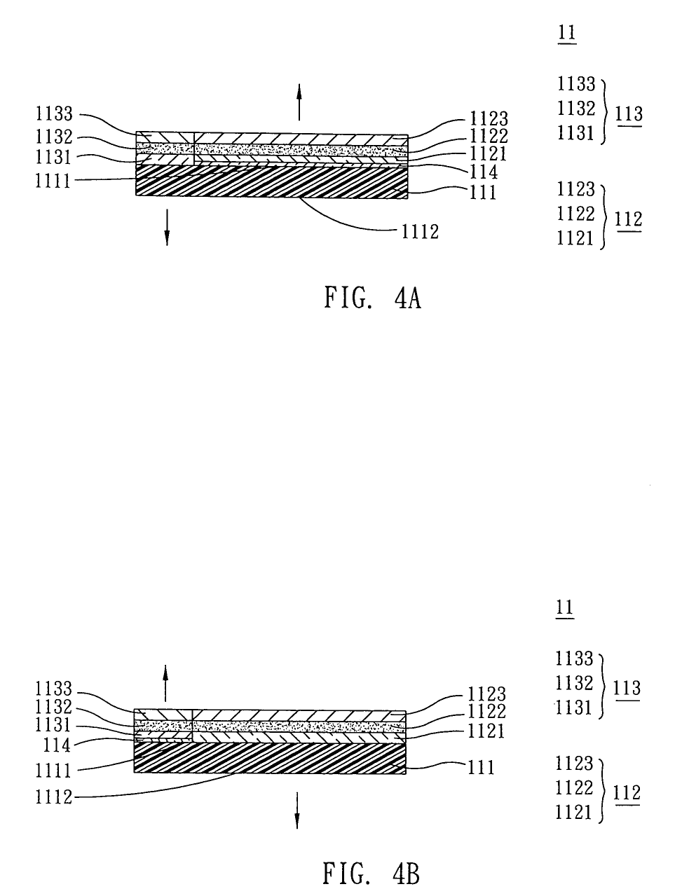

In addition, a reflective layer 114 further may be disposed between the first electrode 1121 of the display area 112 and the first surface 1111 of the substrate 111. This reflective layer 114 is for changing the direction of the light source, as shown in FIG. 4A. Of course, this reflective layer 114 also may be sandwiched between the third electrode 1131 of the light-emitting area 113 and the first surface 1111 of the substrate 111 in order to change the direction of the light source, as shown in FIG. 4B.

### SECOND EMBODIMENT

In addition, referring to FIG. 5, the display module 11 may further comprise another display area 115, which has a fifth electrode 1151, an organic functional layer 1152 and a sixth electrode 1153. The organic functional layer 1152 is sandwiched between the fifth electrode 1151 and the sixth electrode 1153, and the fifth electrode 1151 is disposed on the second surface 1112 of the substrate 111. Herein, the characteristics and functions of the fifth electrode 1151, the organic functional layer 1152 and the sixth electrode 1153 of this embodiment are the same as the first electrode 1121, the organic function layer 1122 and the second electrode 1123 of the first embodiment, and detailed descriptions thereof will be omitted.

### THIRD EMBODIMENT

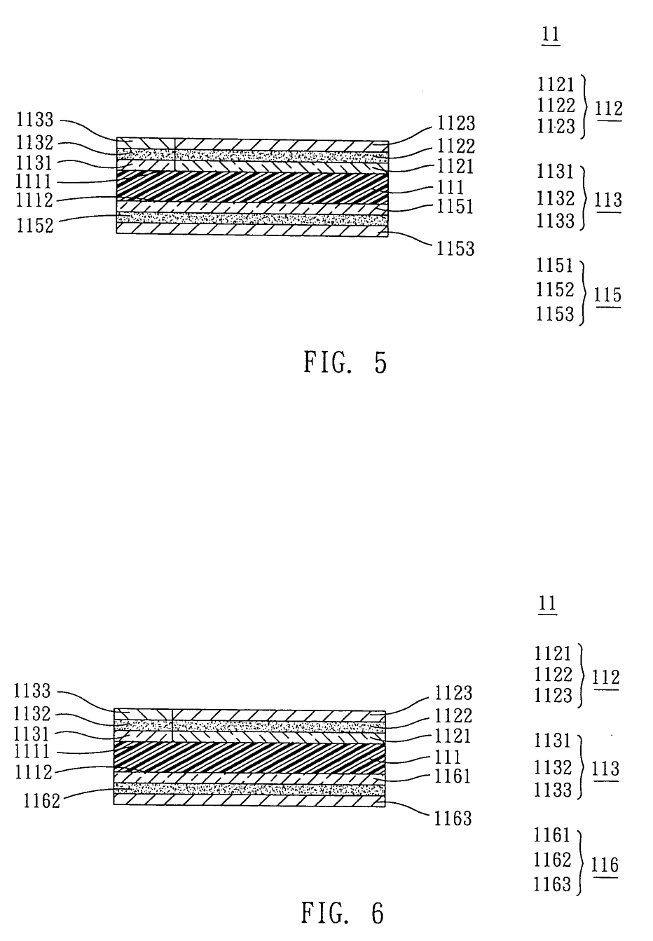

In addition, referring to FIG. 6, the display module 11 may further comprise another light-emitting area 116, which has a seventh electrode 1161, an organic functional layer 1162 and a eighth electrode 1163. The organic functional layer 1162 is sandwiched between the seventh electrode 1161 and the eighth electrode 1163, and the seventh electrode 1161 is disposed on the second surface 1112 of the substrate 111. Herein, the characteristics and functions of the seventh electrode 1161, the organic functional layer 1162 and the eighth electrode 1163 of this embodiment are the same as the third electrode 1131, the organic function layer 1132 and the fourth electrode 1133 of the first embodiment, and detailed descriptions thereof will be omitted.

### FOURTH EMBODIMENT

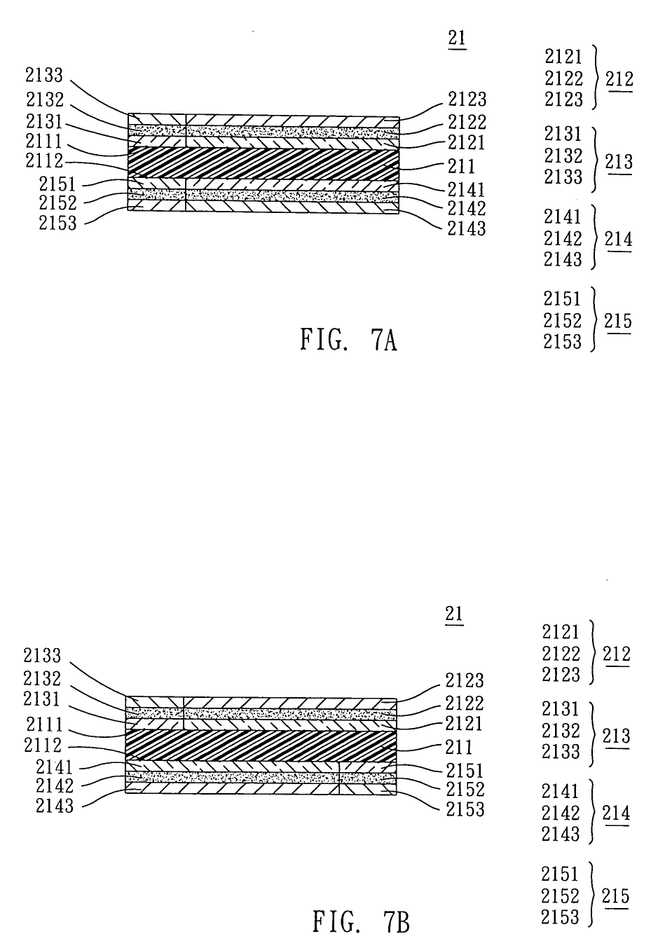

Referring next to FIGS. 7A and 7B, the electronic device with an auxiliary light according to the fourth embodiment of the invention has a display module 21, which comprises a substrate 211, a first display area 212, a first light-emitting area 213, a second display area 214 and a second light-emitting area 215. The substrate 211 has a first surface 2111 and a second surface 2112 opposite to the first surface 2111. The first display area 212 has a first electrode 2121, an organic functional layer 2122 and a second electrode 2123. The organic functional layer 2122 is sandwiched between the first electrode 2121 and the second electrode 2123. The first electrode 2121 is disposed on the first surface 2111 of the substrate 211. The first light-emitting area 213 has a third electrode 2131, an organic functional layer 2132 and a fourth electrode 2133. The organic functional layer 2132 is sandwiched between the third electrode 2131 and the fourth electrode 2133. The third electrode 2131 is disposed on the first surface 2111 of the substrate 211. The second display area 214 has a fifth electrode 2141, an organic functional layer 2142 and a sixth electrode 2143. The organic functional layer 2142 is sandwiched between the fifth electrode 2141 and the sixth electrode 2143. The fifth electrode 2141 is disposed on the second surface 2112 of the substrate 211. The second light-emitting area 215 has a seventh electrode 2151, an organic functional layer 2152 and an eighth electrode 2153. The organic functional layer 2152 is sandwiched between the seventh electrode 2151 and the eighth electrode 2153, and the seventh electrode 2151 is disposed on the second surface 2112 of the substrate 211.

Herein, the characteristics and functions of the substrate 211, the first display area 212, the second display area 214, the first light-emitting area 213 and the second light-emitting area 215 of this embodiment are the same as the substrate 111, the display area 112 and the light-emitting area 113 of the first embodiment, and detailed descriptions thereof will be omitted.

In this embodiment, the first light-emitting area 213 and the second light-emitting area 215 are respectively disposed on the first surface 2111 and the second surface 2112 of the substrate 211, and this configuration is the application form of the dual auxiliary light. The light-emitting areas 213 and 215 also may be disposed at the same side, as shown in FIG. 7A. Of course, the light-emitting areas 213 and 215 may be disposed at different sides, as shown in FIG. 7B. Of course, the relative position relationship between the light-emitting areas 213 and 215 also may be of other forms.

### FIFTH EMBODIMENT

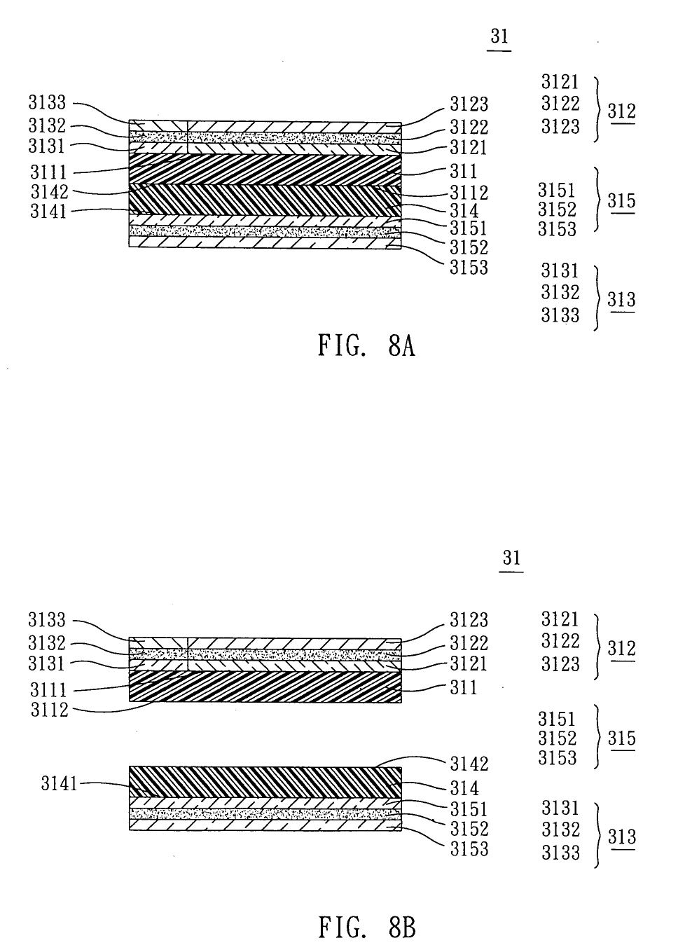

Furthermore, referring to FIGS. 8A and 8B, the electronic device with an auxiliary light according to the fifth embodiment of the invention has a display module 31, which comprises a first substrate 311, a display area 312, a light-emitting area 313, a second substrate 314 and another display area 315. The first substrate 311 has a first surface 3111 and a second surface 3112 opposite to the first surface 3111. The display area 312 has a first electrode 3121, an organic functional layer 3122 and a second electrode 3123. The organic functional layer 3122 is sandwiched between the first electrode 3121 and the second electrode 3123, and the first electrode 3121 is disposed on the first surface 3111 of the first substrate 311. The light-emitting area 313 has a third electrode 3131, an organic functional layer 3132 and a fourth electrode 3133. The organic functional layer 3132 is sandwiched between the third electrode 3131 and the fourth electrode 3133, and the third electrode 3131 is disposed on the first surface 3111 of the first substrate 311. The second substrate 314 has a third surface 3141 and a fourth surface 3142 opposite to the third surface 3141. The fourth surface 3142 of the second substrate 314 is opposite to the second surface 3112 of the first substrate 311. Another display area 315 has a fifth electrode 3151, an organic functional layer 3152 and a sixth electrode 3153. The organic functional layer 3152 is sandwiched between the fifth electrode 3151 and the sixth electrode 3153, and the fifth electrode 3151 is disposed on the third surface 3141 of the second substrate 314.

Herein, the characteristics and functions of the first substrate 311 and the second substrate 314 of this embodiment are the same as the substrate 111 of the first embodiment, the characteristics and functions of the display area 312, the light-emitting area 313 and another display area 315 of this embodiment are the same as the display area 112 and the light-emitting area 113 of the first embodiment, and detailed descriptions thereof will be omitted.

In this embodiment, the second surface 3112 of the first substrate 311 is bonded to the fourth surface 3142 of the second substrate 314, as shown in FIG. 8A. Of course, the second surface 3112 of the first substrate 311 also may be adjacent to the fourth surface 3142 of the second substrate 314, as shown in FIG. 8B.

### SIXTH EMBODIMENT

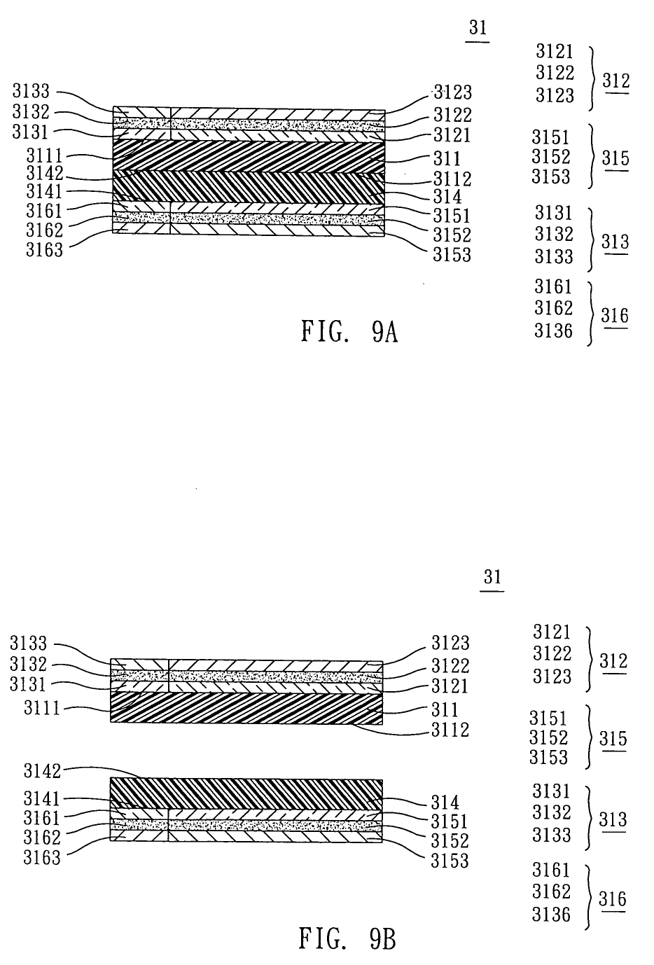

In addition, referring to FIG. 9A and 9B, the display module 31 may further comprise another light-emitting area 316, which has a seventh electrode 3161, an organic functional layer 3162 and a eighth electrode 3163. The organic functional layer 3162 is sandwiched between the seventh electrode 3161 and the eighth electrode 3163, and the seventh electrode 3161 is disposed on the first surface 3141 of the second substrate 341. Herein, the characteristics and functions of another light-emitting area 316 of this embodiment are the same as the light-emitting area 313 of the fifth embodiment, and detailed descriptions thereof will be omitted.

### SEVENTH EMBODIMENT

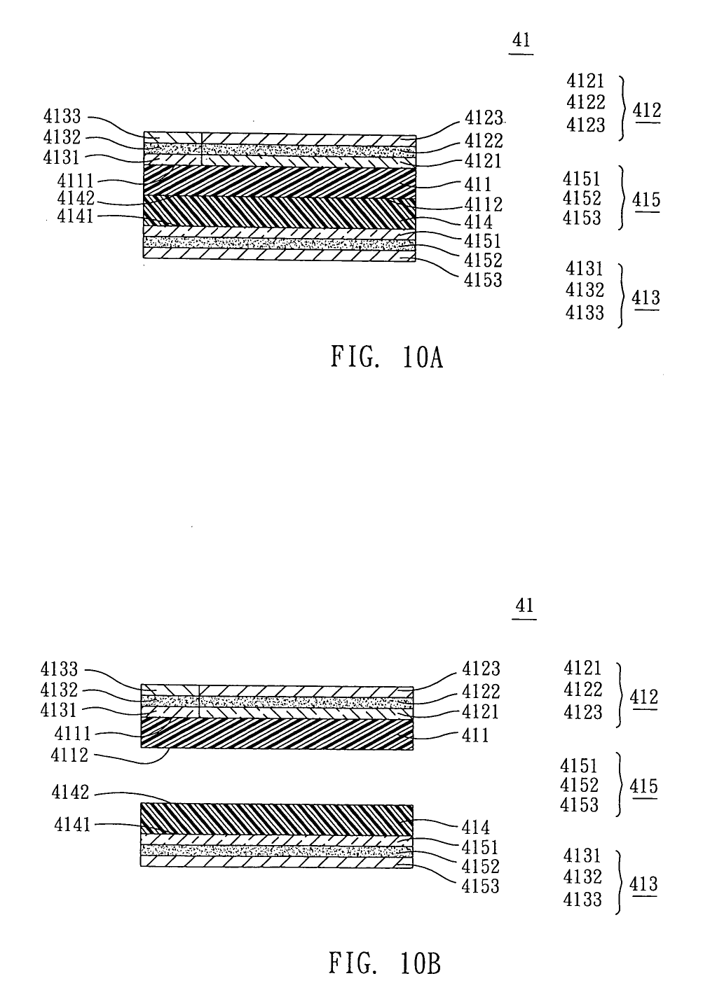

Furthermore, referring to FIGS. 10A and 10B, the electronic device with an auxiliary light according to the seventh embodiment of the invention has a display module 41, which comprises a first substrate 411, a display area 412, a light-emitting area 413, a second substrate 414 and another light-emitting area 415. The first substrate 411 has a first surface 4111 and a second surface 4112 opposite to the first surface 4111. The display area 412 has a first electrode 4121, an organic functional layer 4122 and a second electrode 4123. The organic functional layer 4122 is sandwiched between the first electrode 4121 and the second electrode 4123, and the first electrode 4121 is disposed on first surface 4111 of the first substrate 411. The light-emitting area 413 has a third electrode 4131, an organic functional layer 4132 and a fourth electrode 4133. The organic functional layer 4132 is sandwiched between the third electrode 4131 and the fourth electrode 4133, and the third electrode 4131 is disposed on the first surface 4111 of the first substrate 411. The second substrate 414 has a third surface 4141 and a fourth surface 4142 opposite to the third surface 4141. The fourth surface 4142 of the second substrate 414 is opposite to the second surface 4112 of the first substrate 411. Another light-emitting area 415 has a seventh electrode 4151, an organic functional layer 4152 and an eighth electrode 4153. The organic functional layer 4152 is sandwiched between the seventh electrode 4151 and the eighth electrode 4153, and the seventh electrode 4151 is disposed on the third surface 4141 of the second substrate 414.

Herein, the characteristics and functions of the first substrate 411 and the second substrate 414 of this embodiment are the same as the first substrate 311 and the second substrate 314 of the fifth embodiment, the characteristics and functions of the display area 412, the light-emitting area 413 and another light-emitting area 415 of this embodiment are the same as the display area 112 and the light-emitting area 113 of the first embodiment, and detailed descriptions thereof will be omitted.

In addition, the second surface 4112 of the first substrate 411 is bonded to the fourth surface 4142 of the second substrate 414, as shown in FIG. 10A. Of course, the second surface 4112 of the first substrate 411 also may be adjacent to the fourth surface 4142 of the second substrate 414, as shown in FIG. 10B.

### EIGHTH EMBODIMENT

Furthermore, referring to FIG. 11, the electronic device with an auxiliary light according to eighth embodiment of the invention includes a display module 51. The display module 51 comprises a substrate 511, a display area 512 and a light-emitting area 513. The substrate 511 has a first surface 5111 and a second surface 5112 opposite to the first surface 5111. The display area 512 has a first electrode 5121, an organic functional layer 5122 and a second electrode 5123. The organic functional layer 5122 is sandwiched between the first electrode 5121 and the second electrode 5123, and the first electrode 5121 is disposed on the first surface 5111 of the substrate 511. The light-emitting area 513 has a third electrode 5131, an organic functional layer 5132 and a fourth electrode 5133. The organic functional layer 5132 is sandwiched between the third electrode 5131 and the fourth electrode 5133, and the third electrode 5131 is disposed on the second surface 5112 of the substrate 511.

Herein, the characteristics and functions of the substrate 511, the display area 512 and the light-emitting area 513 of this embodiment are the same as those of the first embodiment, and detailed descriptions thereof will be omitted.

The electronic device of the invention with auxiliary light further has a housing (not shown in the drawing), the shape and dimension of which may be adjusted according to the requirement so that the display module may be received therein.

The electronic device of the invention with auxiliary light further has an image capture unit (not shown in the drawing) for capturing the static images or dynamic images.

The electronic device of the invention with an auxiliary light further has an input unit (not shown in the drawing). Herein, the input unit may be a key-type input unit, a touch input unit, a voice-controlled input unit, or the like.

The electronic device of the invention with an auxiliary light further has an information processing module (not shown in the drawing). Herein, the information processing module includes a microprocessor, a memory, a signal processor, and the like. Of course, the information processing module may also include a communication interface (e.g., transmitter and receiver).

The electronic device of the invention with an auxiliary light further has a power supply unit, such as a battery (not shown in the drawing), for supplying the required power.

An embodied example of the invention will be illustrated by using the mobile phone as the example. A mobile phone 6 includes a housing 61, an OELD panel 62, an image capture unit 63 and an input unit 64, wherein the OELD panel 62, the image capture unit 63 and the input unit 64 are disposed in the housing 61, and the OELD panel 62 has a display area 621 and a light-emitting area 622, as shown in FIG. 12. When the user operates the mobile phone 6 to catch the target image, the image capture unit 63 can catch the target image and directly display the image on the display area 621 of the OELD panel 62 for the purpose of preview. Of course, the image catched by the image capture unit 63 also may be transmitted to the information processing module (not shown) and then be stored. When the photograph is being taken and the environment light intensity is insufficient, the light-emitting area 622 can provide the auxiliary light to enhance the light intensity for the photographing process, and thus serve as a flash. In addition, when user wants to change to or enhance specific color system, the light-emitting area 622 also may make the modulation and compensation according to the color required by the user. In addition, when the environmental light intensity for photographing is sufficient, the light-emitting area 622 also may provide the display function. That is, the desired voltage is applied according to various conditions such that the light-emitting area 622 may match with the display area 621 and both of them may serve as the display panel. In this case, the display area 621 and the light-emitting area 622 are driven, respectively.

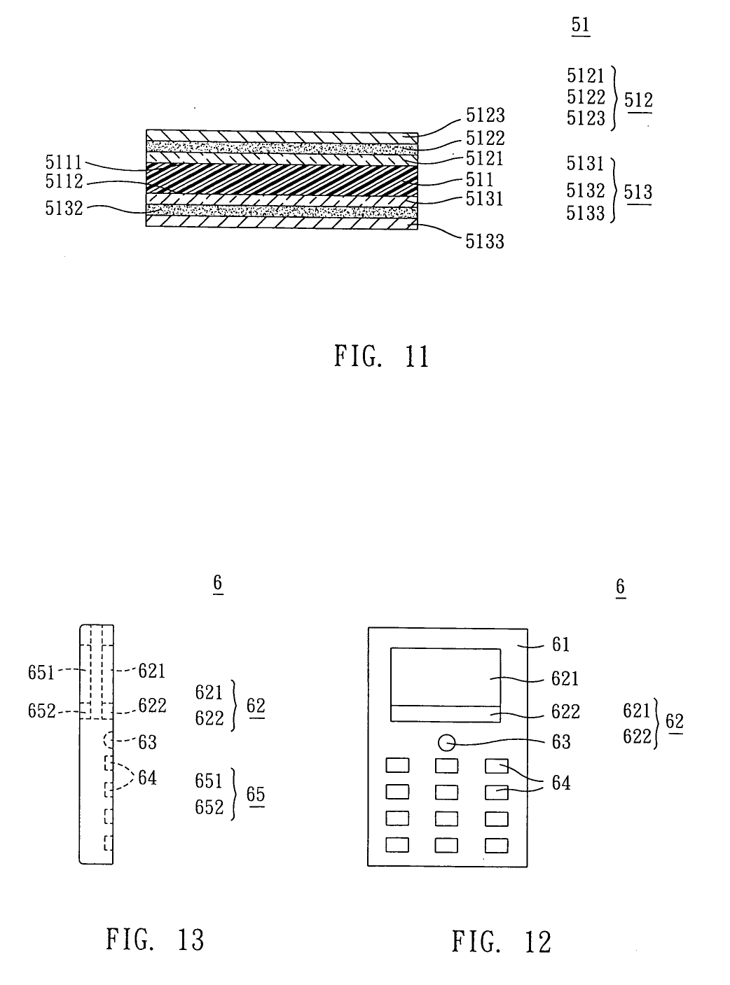

Furthermore, the mobile phone 6 may also include another OELD panel 65, which has a display area 651 and a light-emitting area 652 and is disposed on a surface opposite to the surface of the housing 61 on which the OELD panel 62 is disposed, as shown in FIG. 13. This design is the application of the dual light sources.

Of course, the light-emitting area of the invention also may be disposed on electronic device independently. That is, this light-emitting area does not have to be used in conjunction with the image capture unit. In this case, the light-emitting area may provide the function of a flash.

In addition, the following comparison table shows the unique advantages of this invention over conventional technologies.

| | Conventional | Conventional | |
|---|---|---|---|
| | auxiliary light | plane display | Display module |
| | (e.g., flash) | panel | of the invention |
| Function of | Yes | No | Yes |
| light compensation | | | |
| in photographing | | | |
| Panel display | No | Yes | Yes |
| function | | | |
| Dual light | No | No | Yes |
| compensation | | | |
| function | | | |
| High | No | No | Yes |
| efficiency in | | | |
| component | | | |
| assembly | | | |
| Ornamental | No | No | Yes |
| function | | | |

Of course, the electronic device of this invention includes, but not limited to, a mobile phone, a digital still camera (DSC), digital video recorder (DVR), a hand-held computer (hand-held PC), a personal digital assistant (PDA), a digital voice recorder, an e-book, a stock quote machine, and the like.

As mentioned above, the electronic device with an auxiliary light according to the invention has an OELD panel having the display function and the auxiliary light function combined together. That is, the invention utilizes the self-emissive and high brightness properties of the OELD panel so that the device has the functions of displaying information, images and videos as well as the special functions of serving as the auxiliary light (e.g., flash light). Compared to the prior art, the invention has the display function and the auxiliary light function in a single module by only applying state-of-the-art processing technology to the original OELD panel without adding an extra auxiliary light source module. In this case, the number of assembly modules can be reduced, the assembling space of the module can become compact, and the electronic device can meet the requirement of miniaturization. Meanwhile, the manufacturing process is less complicated, which will results in lower production costs, with shorter manufacturing lead-time. And this will generates higher productivity and higher product value. Thus, the invention is very suitable for the practical product application and manufacturing. In addition, light-emitting areas may be respectively disposed on two opposite surfaces of the substrate in this invention such that the invention may also have the dual auxiliary light functions, and this will make product more value-added and to meet different market requirements.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An electronic device with auxiliary light, wherein the electronic device has a display module, and the display module comprises:
a substrate having a first surface and a second surface opposite to the first surface;
a display area having a first electrode, an organic functional layer and a second electrode, wherein the organic functional layer is sandwiched between the first electrode and the second electrode, and the first electrode is disposed on the first surface of the substrate; and
a light-emitting area having a third electrode, an organic functional layer and a fourth electrode, wherein the organic functional layer is sandwiched between the third electrode and the fourth electrode, and the third electrode is disposed on the first surface or the second surface of the substrate.

2. The electronic device according to claim 1, wherein the display module further comprises a reflective layer sandwiched between the first electrode of the display area and the first surface of the substrate, between the third electrode of the light-emitting area and the first surface of the substrate, or between the third electrode of the light-emitting area and the second surface of the substrate.

3. The electronic device according to claim 1, wherein the display module further comprises another display area having a fifth electrode, an organic functional layer and a sixth electrode, the organic functional layer is sandwiched between the fifth electrode and the sixth electrode, and the fifth electrode is disposed on the second surface of the substrate.

4. The electronic device according to claim 1, wherein the display module further comprises another light-emitting area having a seventh electrode, an organic functional layer and an eighth electrode, the organic functional layer is disposed between the seventh electrode and the eighth electrode, and the seventh electrode is opposite to third electrode and disposed on another surface of the substrate.

5. The electronic device according to claim 1, wherein the substrate is a transparent substrate or an opaque substrate.

6. The electronic device according to claim 1, wherein the substrate is a rigid substrate or a flexible substrate.

7. The electronic device according to claim 1, wherein the light-emitting area is disposed on at least one side of the display area or the display area is disposed on at least one side of the light-emitting area.

8. The electronic device according to claim 1, wherein the electronic device is a mobile phone, a digital still camera or a personal digital assistant.

9. The electronic device according to claim 1, wherein the electronic device further has an image capture unit.

10. An electronic device with auxiliary light, wherein the electronic device has a display module, and the display module comprises:
a substrate having a first surface and a second surface opposite to the first surface;
a first display area having a first electrode, an organic functional layer and a second electrode, wherein the organic functional layer is sandwiched between the first electrode and the second electrode, and the first electrode is disposed on the first surface of the substrate;
a first light-emitting area having a third electrode, an organic functional layer and a fourth electrode, wherein the organic functional layer is sandwiched between the third electrode and the fourth electrode, and the third electrode is disposed on the first surface of the substrate;
a second display area having a fifth electrode, an organic functional layer and a sixth electrode, wherein the organic functional layer is sandwiched between the fifth electrode and the sixth electrode, and the fifth electrode is disposed on second surface of the substrate; and
a second light-emitting area having a seventh electrode, an organic functional layer and an eighth electrode, wherein the organic functional layer is disposed between the seventh electrode and the eighth electrode, and the seventh electrode is disposed on second surface of the substrate.

11. The electronic device according to claim 10, wherein the first light-emitting area is disposed on at least one side of the first display area or the first display area is disposed on at least one side of the first light-emitting area.

12. The electronic device according to claim 10, wherein the second light-emitting area is disposed on at least one side of the second display area or the second display area is disposed on at least one side of the second light-emitting area.

13. The electronic device according to claim 10, wherein the electronic device further has an image capture unit.

14. An electronic device with auxiliary light, wherein the electronic device has a display module, and the display module comprises:
a first substrate having a first surface and a second surface opposite to the first surface;
a display area having a first electrode, an organic functional layer and a second electrode, wherein the organic functional layer is sandwiched between the first electrode and the second electrode, and the first electrode is disposed on the first surface of the first substrate;
a light-emitting area having a third electrode, an organic functional layer and a fourth electrode, wherein the organic functional layer is sandwiched between the third electrode and the fourth electrode, and the third electrode is disposed on the first surface of the first substrate;
a second substrate having a third surface and a fourth surface opposite to the third surface, wherein the fourth surface of the second substrate is opposite to the second surface of the first substrate; and
another display area having a fifth electrode, an organic functional layer and a sixth electrode, wherein the organic functional layer is sandwiched between the fifth electrode and the sixth electrode, and the fifth electrode is disposed on the third surface of the second substrate.

15. The electronic device according to claim 14, wherein the display module further comprises another light-emitting area, which has a seventh electrode, an organic functional layer and an eighth electrode, wherein the organic functional layer is disposed between the seventh electrode and the eighth electrode, and the seventh electrode is disposed on the third surface of the second substrate.

16. The electronic device according to claim 14, wherein the second surface of the first substrate is bonded to the fourth surface of the second substrate or the second surface of the first substrate is adjacent to the fourth surface of the second substrate.

17. The electronic device according to claim 14, wherein the first substrate or the second substrate is a rigid substrate or a flexible substrate.

18. The electronic device according to claim 14, wherein the light-emitting area is disposed on at least one side of the display area or the display area is disposed on at least one side of the light-emitting area.

19. The electronic device according to claim 15, wherein another light-emitting area is disposed on at least one side of another display area or another display area is disposed on at least one side of another light-emitting area.

20. The electronic device according to claim 14, wherein the electronic device further has an image capture unit.
